(19) United States
(12) Patent Application Publication
(10) Pub. No.: US 2009/0117664 A1
(43) Pub. Date: May 7, 2009

(54) LIQUID SENDING METHOD OF LIQUID IN SUBSTRATE CHANNEL AND LIQUID SENDING APPARATUS

(76) Inventor: Masataka SHINODA, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/264,867

(22) Filed: Nov. 4, 2008

(30) Foreign Application Priority Data
Nov. 5, 2007 (JP) P2007-286878
Jul. 28, 2008 (JP) P2008-193130

(51) Int. Cl. G01N 21/64; B01L 3/00; B81B 7/02; B03C 1/30

(52) U.S. Cl. 436/172; 422/99; 137/827; 209/39

(57) ABSTRACT

A liquid sending method includes the step of introducing either one fluid of a gas or an insulating liquid into a channel disposed on a substrate, thereby dividing a liquid flowing in the channel and sending the liquid.

### CROSS REFERENCES TO RELATED APPLICATIONS

The present invention contains subjects related to Japanese Patent Applications JP 2007-286878 and JP 2008-193130 filed in the Japan Patent Office on Nov. 5, 2007 and Jul. 28, 2008, respectively, the entire contents of which being incorporated herein by reference.

### BACKGROUND OF THE INVENTION

1. Field of the Invention

The present invention relates to a liquid sending method of a liquid in a channel disposed on a substrate and to a reaction analysis method and a liquid sending apparatus utilizing this method. In more detail, the present invention relates to a liquid sending method for introducing a fluid into a channel, thereby dividing the fluid flowing in the channel and sending it and to others.

2. Description of the Related Art

In recent years, there have been developed microchips on which by applying a microfabrication technology in the semiconductor industry, a reaction region or a channel for performing a chemical and biological analysis is provided. These microchips start to be utilized for, for example, an electrochemical detector of liquid chromatography or a small-sized electrochemical sensor in clinical practice.

An analysis system using such a microchip is called μ-TAS (micro-total-analysis system), a lab-on-a-chip, a biochip or the like and is watched as a technology capable of realizing a high speed and highly effective chemical and biological analysis and its integration, or of downsizing an analysis system.

The μ-TAS is expected to be applied to a biological analysis particularly of a precious trace sample or a number of specimens because it is possible to achieve an analysis with a small amount of a sample and it is possible to achieve disposal use of the chip.

JP-T-2005-538287 (Patent Document 1) is directed to a liquid treatment system in μ-TAS and discloses a micro pumping system for performing pumping, mixing or valve switching by a bubble formed in a micro channel by movable light beam (see claims 1, 55, 56 and 60). This micro pumping system can be used for analysis such as diagnostics or high through put screening, or for synthesis of, for example, combinatorial chemical libraries (see paragraph [0144]).

Application examples of μ-TAS to the biological analysis include a fine particle aliquoting technology for optically analyzing properties of fine particles such as cells in a channel provided on a microchip and sorting and recovering a population meeting a prescribed requirement among the fine particles.

In connection with this fine particle aliquoting technology, JP-A-7-24309 (Patent Document 2) discloses a particle sorting apparatus utilizing laser trapping. In this particle sorting apparatus, by irradiating a moving particle such as a cell with scanning light, an acting force is imparted according to the type of the particle, thereby aliquoting the particle.

As a technology of the same type, JP-A-2004-167479 (Patent Document 3) discloses a fine particle recovering apparatus utilizing an optical force or an optical pressure. In this fine particle recovering apparatus, a laser beam is irradiated on a channel of a fine particle intersecting the flow direction of the fine particle, and the moving direction of the fine particle to be recovered is biased in the convergent direction of the laser beam, thereby recovering the fine particle.

Also, JP-A-2003-107099 (Patent Document 4) discloses a fine particle sorting microchip having an electrode for controlling the moving direction of a fine particle. This electrode is disposed in the vicinity of a channel port from a fine particle measuring site to a fine particle sorting channel, thereby controlling the moving direction of the fine particle by a mutual action with an electric field.

### SUMMARY OF THE INVENTION

As disclosed in Patent Documents 1 to 4, in the existing μ-TAS, a prescribed chemical reaction was carried out in a liquid to be continuously sent in a channel. Also, in case of aliquoting a fine particle, by imparting an acting force directly to the fine particle in the liquid flowing continuously in a fixed direction in a channel by laser trapping, optical force or optical pressure, electricity, etc., the fine particle was moved in a direction different from the flow direction of the liquid against the flow. For that reason, in order to control the sending direction of the fine particle, it was necessary to impart a considerably large acting force to the fine particle.

For that reason, only a single reaction or a series of continued reactions can be carried out in a liquid flowing in a channel, and therefore, plural independent chemical reactions could not be carried out in the channel. In the system of imparting an acting force directly to a fine particle by laser trapping, optical force or optical pressure, electricity, etc., it was difficult to impart a sufficient acting force for controlling the sending direction of the fine particle at a high speed and with high precision.

Then, it is desirable to provide a technology for dividing the continuity of a liquid flowing in a channel disposed on a substrate and sending the liquid.

In an embodiment according to the present invention, there is provided a liquid sending method for introducing either one fluid of a gas or an insulating liquid into a channel disposed on a substrate, thereby dividing a liquid flowing in the channel and sending the liquid.

In this liquid sending method, in the case where a dispersion of fine particles is flown in the channel, by introducing the fluid between the fine particles, it is possible to divide the dispersion flowing in the channel every prescribed number of fine particles and to send the liquid.

In that case, by further controlling the sending direction on the basis of charge or magnetization imparted to the divided dispersion, it is possible to sort the fine particles.

By injecting a material into the divided dispersion and detecting a reaction between the material and the fine particle, the charge can be imparted on the basis of the detection result.

Also, in an embodiment according to the present invention, there is provided a reaction analysis method including the steps of injecting plural materials into the divided liquid by the foregoing method and detecting a reaction between the materials.

This reaction analysis method may further include the steps of injecting a micro bead for identification into the divided liquid and detecting an identification signal from the micro bead for identification.

In that case, the identification signal can be detected by measuring at least one of the following: temperature, fluorescence, scattered light, magnetization, charge, shape and concentration, of the micro bead for identification.

Furthermore, in an embodiment according to the present invention, there is provided a liquid sending apparatus including a fluid introduction part for introducing either one fluid of a gas or an insulating liquid into a channel disposed on a substrate, thereby dividing a liquid flowing in the channel and sending the liquid.

In this liquid sending apparatus, it is favorable to impart hydrophobic property or electrical insulating property to the surface of the channel facing the liquid.

The term “liquid” as referred to in the specification and claims should be interpreted in a broad sense and may include a uniform liquid, a suspension, namely a liquid containing fine particles, a liquid containing small bubbles, an aqueous liquid, an organic liquid, a two-phase based or hydrophobic liquid and a hydrophilic liquid.

Also, the term “gas” should not be interpreted in a narrow sense and may broadly include air and gases such as nitrogen.

The term “fine particle” as referred to in the specification and claims widely includes cells, microorganisms, biological polymer materials such as liposome, and fine particles such as synthetic particles, for example, latex particles, gel particles, industrial particles, etc. Examples of the objective cell include animal cells (for example, blood cells, etc.) and vegetable cells. Examples of the microorganism include bacteria such as a colon bacillus, viruses such as a tobacco mosaic virus and fungi such as a yeast fungus. Examples of the biological polymer material include chromosomes constituting various cells, liposome, mitochondria and an organelle. Furthermore, fine particles obtained by chemically or physically modifying and solidifying a biological polymer material (for example, DNA, proteins, antibodies, etc.) on the surface or in the inside of a fine particle of glass, polystyrene or the like may also be included. Also, the industrial particle may be, for example, an organic or inorganic polymer material, or a metal. Examples of the organic polymer material include polystyrene, styrene/divinylbenzene and polymethyl methacrylate. Examples of the inorganic polymer material include glass, silica and magnetic materials. Examples of the metal include gold colloid and aluminum. Though the shape of such fine particles is in general spherical, it may be non-spherical; and the size and mass thereof are not particularly limited.

According to the present invention, there is provided a technology for dividing the continuity of a liquid flowing in a channel disposed on a substrate and sending the liquid.

### BRIEF DESCRIPTION OF THE DRAWINGS

FIG. 1 is a schematic view (top view) showing a channel disposed on a substrate of a liquid sending apparatus according to First Embodiment of the present invention.

FIG. 2 is a schematic view (top view) showing a channel through which a dispersion of fine particles is flown in a liquid sending apparatus according to Second Embodiment of the present invention.

FIG. 3 is a view explaining one example of switching timing of a valve of a fluid introduction part in Second Embodiment.

FIG. 4 is a view explaining another example of switching timing of a valve of a fluid introduction part in Second Embodiment.

FIG. 5 is a schematic view (top view) showing a channel in case of dividing a dispersion every two fine particles in the liquid sending apparatus according to Second Embodiment of the present invention.

FIG. 6 is a schematic view (top view) showing a channel disposed on a substrate of a liquid sending apparatus according to Third Embodiment of the present invention.

FIG. 7 is a view explaining one example of charge timing of a charge part in Third Embodiment.

FIG. 8 is a schematic view (top view) showing a channel disposed on a substrate of a liquid sending apparatus according to Fourth Embodiment of the present invention.

FIG. 9 is a view explaining one example of charge timing of a charge part in Fourth Embodiment.

FIG. 10 is a schematic view (top view) showing a channel disposed on a substrate of a liquid sending apparatus according to Fifth Embodiment of the present invention.

FIG. 11 is a view explaining one example of charge timing of a charge part in Fifth Embodiment.

FIG. 12 is a schematic view (top view of channel) explaining a reaction analysis method utilizing a liquid sending method according to an embodiment of the present invention.

### DESCRIPTION OF THE PREFERRED EMBODIMENTS

Preferred embodiments for carrying out the present invention are hereunder described with reference to the accompanying drawings. The embodiments are described below merely by way of example of the present invention, and it should be construed that the scope of the present invention is never narrowly interpreted thereby.

### 1. Liquid Sending Method and Liquid Sending Apparatus

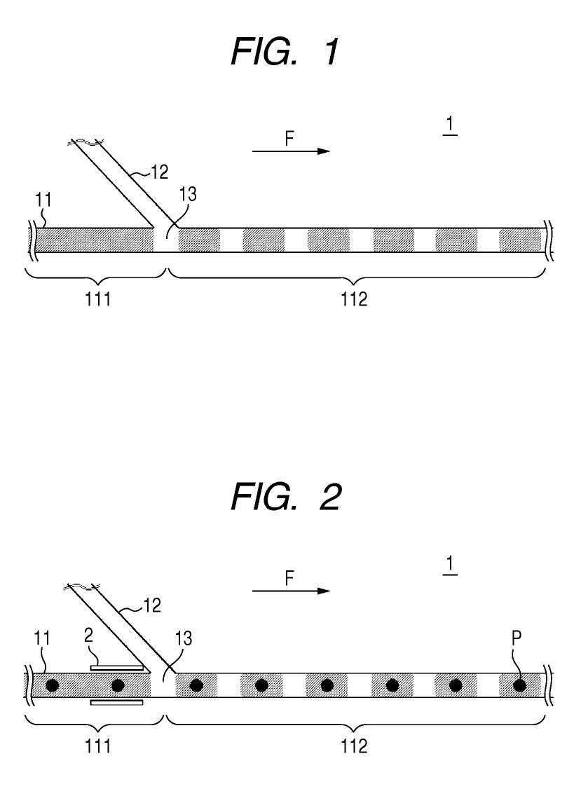

FIG. 1 is a schematic view (top view) showing a channel disposed on a substrate of a liquid sending apparatus according to First Embodiment of the present invention. While a plural number of channels can be disposed on a substrate, a single channel is representatively shown and described herein.

In FIG. 1, a symbol 1 stands for a substrate; and a symbol 11 stands for a channel. A liquid (shown by oblique lines in FIG. 1) to be introduced into the channel 11 is sent in a direction of an arrow F from the left side to the right side in FIG. 1.

The substrate 1 is in general formed of glass or a plastic of every kind (for example PP, PC, COP, PDMS, etc.). In case of glass, the channel 11 is formed by wet etching or dry etching; and in case of a plastic, the channel 11 is formed by nanoinprinting, injection molding or cutting processing.

As described later, in the case where a gas is introduced into the channel 11, in order to completely divide the liquid in the channel, it is preferable that the substrate 1 is formed of a hydrophobic material. Also, the surface of the channel 11 may be subjected to hydrophobic processing. As to the hydrophobic processing, hydrophobic property can be imparted by a surface treatment by coating of a usually used silicon resin based hydrophobic material or fluorocarbon resin based hydrophobic material, or fabrication of an acrylic silicone hydrophobic film, a fluorine hydrophobic film, etc. and besides, formation of a fine structure on the surface of the channel.

In FIG. 1, a symbol 12 stands for a fluid introduction part for introducing the fluid into the channel 11. One end of the fluid introduction part 12 is communicated with the channel 11, and either one fluid of a gas or an insulating liquid to be supplied by non-illustrated delivery means is introduced into the channel 11 from the other end of the fluid introduction part 12. As the delivery means, a usually used pressure pump or the like can be adopted. Hereinafter, a portion where the fluid introduction part 12 is communicated with the channel is referred to as a “connection part 13”; an upstream of the connection part 13 of the channel 11 is referred to as an “introduction route 111”; and a downstream of the connection part 13 of the channel 11 is referred to as a “liquid sending route 112”.

In the liquid sending apparatus according to the embodiment of the present invention, by introducing a fluid from the fluid introduction part 12 into the connection part at a prescribed timing, the liquid to be sent from the introduction part 111 is divided by the fluid and sent to the liquid sending route 112.

In FIG. 1, though the case where one fluid introduction part 12 is provided is illustrated, two or more fluid introduction parts 12 to be communicated in the connection part can be provided. For example, the fluid may be introduced into the connection part 13 from the both directions of the channel 11 (the up and down directions in FIG. 1) by providing fluid introduction parts 12, 12 on the both sides of the connection part 13 (the top and bottom sides in FIG. 1).

### 2. Liquid Sending Method of Dispersion of Fine Particles and Liquid Sending Apparatus

FIG. 2 is a schematic view (top view) showing a channel 11 through which a dispersion of fine particles is flown in a liquid sending apparatus according to Second Embodiment of the present invention.

In FIG. 2, a symbol P stands for a fine particle to be contained in the dispersion. Also, a symbol 2 stands for a detection part for detecting the fine particle P in the dispersion to be sent in the introduction route 111.

In this embodiment, a configuration in which the detection part 2 is disposed as a pair of microelectrodes on the both sides of the introduction route 111 on a substrate 1, and an alternating voltage is applied between the electrodes, thereby detecting the fine particle P due to a change of impedance flowing between the electrodes is adopted.

The detection part 2 may be, for example, of a configuration for optically detecting the fine particle P. For example, the detection part 2 can be configured of a known optical detection system in the fine particle aliquoting technology disclosed in the foregoing Patent Documents 2 to 4. In that case, as the detection part 2, a laser light source and an optical path for condensing and irradiating the laser light from the light source in a prescribed site of the introduction route 111 are provided. Then, the light emitted from the fine particle P in the introduction route 111 upon irradiation with laser light is guided through the same or different optical paths into and detected by a detector, thereby detecting the fine particle P. On that occasion, the light for performing the detection may be scattered light or fluorescence emitted from the fine particle P upon irradiation with laser light or the like.

In the case where the detection part 2 is configured as an optical detection system, it is desirable that the substrate 1 is able to transmit the laser light to be used therethrough and is formed of a material which is small in wavelength dispersion against the laser light and small in optical error.

In the liquid sending apparatus according to the embodiment of the present invention, by controlling the switching timing of a valve (not-illustrated) of the delivery means of the fluid introduction part 12, the fluid is introduced between the fine particles P in the connection part 13, and the dispersion is divided every prescribed number of the fine particles P and sent to the liquid sending route 112 (FIG. 2 shows the case where the dispersion is divided every one fine particle).

The number of the fine particles P to be contained in the divided dispersion can be arbitrarily set 2 by controlling the switching timing of the valve of the fluid introduction part 12 according to a detection signal from the detection part.

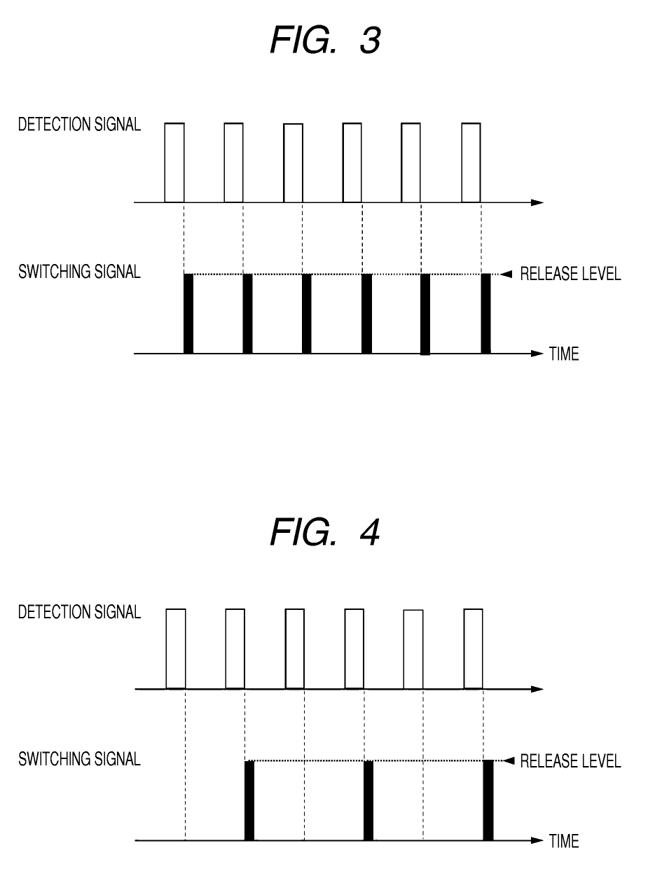

FIG. 3 shows one example of the switching timing of the valve of the fluid introduction part 12. In FIG. 3, a detection signal of the fine particle P by the detection part 2 is chronologically shown in the upper row; and a switching signal to be inputted into the valve of the fluid introduction part 12 is chronologically shown in the lower row.

FIG. 3 represents the switching timing of the valve of the fluid introduction part 12 in the case where the dispersion is divided ever one fine particle P (see FIG. 2). As shown in FIG. 3, by inputting the switching signal into the valve of the fluid introduction part 12 every detection signal of the fine particle P from the detection part 2 and introducing the fluid into the connection part 13, it is possible to divide the dispersion every one fine particle.

On that occasion, a delay time of the switching signal against the detection signal is properly set according to a sending rate of the fine particle P in the introduction route 111 and a distance between the detection part 3 and the connection part 3.

FIG. 4 shows another example of the switching timing of the valve of the fluid introduction part 12.

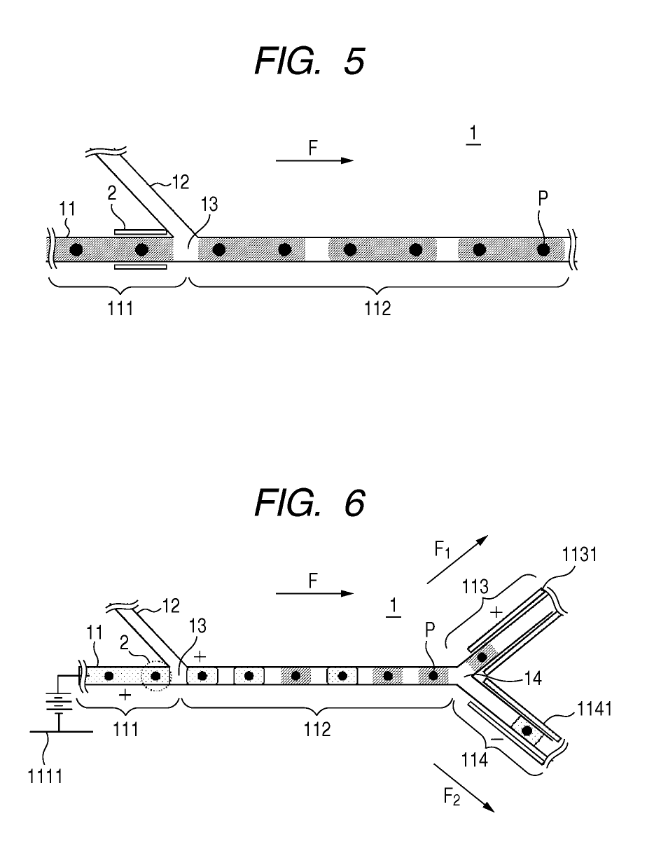

FIG. 4 shows the case where the switching signal is outputted into the valve of the fluid introduction part 12 every two detection signals of the fine particle P which are outputted from the detection part 2, thereby introducing the fluid into the connection part 13. In that case, as illustrated in FIG. 5, the dispersion is divided every two fine particles and sent to the liquid sending route 112.

As illustrated in FIGS. 2 and 5, it is not required that the fine particle P to be sent to the introduction route 111 is always sent at regular intervals. Even in the case where the fine particle P is sent at irregular intervals, by outputting the switching signal to the valve of the fluid introduction part 12 according to the detection signal of the fine particle P from the detection part 2, it is possible to divide the dispersion every an arbitrary number of the fine particles P.

### 3. Aliquoting of Fine Particle

Next, explanation is made on the case of carrying out aliquoting of the fine particle P in the liquid sending apparatus according to the embodiment of the present invention.

FIG. 6 is a schematic view (top view) showing a channel disposed on a substrate of a liquid sending apparatus according to Third Embodiment of the present invention.

The channel 11 of the liquid sending apparatus according to this embodiment is provided with branch channels 113 and 114 which are branched from the liquid sending route 112 in a branch part shown by a symbol 14 in FIG. 6. In this liquid sending apparatus, it is possible to selectively send the dispersion to be divided and sent to the liquid sending route 112 to either one of the branch channel 113 or the branch channel 114.

The sending direction in the branch part 14 can be controlled on the basis of charge or magnetization to be imparted to the divided dispersion. Specific procedures and configuration thereof are hereunder described.

In FIG. 6, a symbol 1111 stands for a charge part for applying a voltage to the dispersion in the introduction route 111. In the charge part 1111, a plus or minus voltage is applied to the dispersion in the introduction route 111 when the fluid is introducted from the fluid introduction part 12 into the connection part 13. According to this, it is possible to impart a plus or minus charge to the dispersion to be divided into the liquid sending route 112 by introducing the fluid.

The branch channels 113 and 114 are charged plus or minus by a pair of electrodes 1131, 1131 and a pair of electrodes 1141, 1141 which are disposed on the both sides of the branch channels 113 and 114 and charged plus or minus, respectively. The dispersion charged by the charge part 1111 and divided into the liquid sending route 112 are sent to the branch channel which is charged opposite to the charge in the branch part 14.

In FIG. 6, the case where the electrodes 1131, 1131 of the branch channel 113 are charged plus, and the electrodes 1141, 114 of the branch channel 114 are charged minus is illustrated. According to this, it is possible to send the minus charged dispersion (shown by oblique lines in FIG. 6) to the branch channel 113 and to send the plus charged dispersion (shown by dots in FIG. 6) to the branch channel 114, whereby it becomes possible to sort the fine particles P contained in the dispersion into two groups.

Also, in the case where the sending direction in the branch part 14 is controlled on the basis of magnetization imparted to the dispersion, a material capable of holding the magnetization such as a magnetic micro bead is mixed in the dispersion, and the mixture is sent to the branch channel 113 or the branch channel 114 positioned on the N pole side or the S polar side in the branch part 14 on the basis of a magnetic repulsion between the material and a magnetic field generated by a magnetic field generator such as a coil provided in the liquid sending apparatus.

In order to keep the charge or magnetization of the dispersion divided into the liquid sending route 112, it is preferable to use a gas for the fluid. On that occasion, when the division of the dispersion in the liquid sending route 112 is incomplete, and the adjacent dispersions are partially communicated with each other, there is a possibility that the charge or magnetization of the dispersion disappears, whereby the control in the sending direction becomes impossible or inaccurate. Accordingly, for the purposes of completely dividing the dispersion by the gas to be introduced and keeping insulating properties between the divided dispersions, it is desirable to impart hydrophobic property on the surface of the channel 11 (liquid sending route 112). Furthermore, it is also effective to obstruct the migration of a charge between the divided dispersions by imparting electrical insulating property on the surface of the channel 11 (liquid sending route 112). The electrical insulating property may be imparted by, for example, coating or fabrication of a material with insulating property on the surface of the channel. Also, it is possible to obstruct electricity between the dispersions by flowing a liquid with insulating property such as ultra-pure water onto the surface of the channel.

Also, in order to keep the charge or magnetization of the dispersion divided into the liquid sending route 112, a liquid with electrical or magnetic insulating property (“insulating liquid”) may be used as the fluid. For this insulating liquid, for example, the foregoing ultra-pure water or the like is used. According to this, it is possible to obstruct the migration of charge or magnetization between the divided dispersions.

It is possible to sort the fine particle P on the basis of a result obtained by judging properties of the fine particle P by the detection part 2. In this embodiment, the detection of the fine particle P and the judgment of optical properties are carried out by configuring the detection part 2 as the optical detection system as described previously and detecting light emitted upon irradiation of the fine particle P in the introduction route 111 with laser light. An irradiation spot of the laser light in the introduction route 111 is illustrated as a circular region surrounded by a dotted line in FIG. 6.

A parameter for analyzing the optical properties of the fine particle P may be, for example, forward scattered light for measuring the size of a fine particle, side scattered light for measuring the structure, scattered light of Rayleigh scattering, or Mie scattering, fluorescence or the like according to the objective fine particle and aliquoting purpose. The detection part 2 analyzes the light detected by such parameters, thereby judging whether or not the fine particle P has prescribed optical properties.

In the case where the detection parts 2 judges that the fine particle P has desired optical properties, the detection part 2 outputs a positive signal into the charge part 1111 and charges the dispersion in the introduction route 111 either plus or minus. The “positive signal” as referred to herein is a sorting signal obtained from the dispersion containing a fine particle having desired properties, and the sending direction in the branch part 14 is controlled on the basis of this sorting signal (positive signal), thereby aliquoting the fine particle.

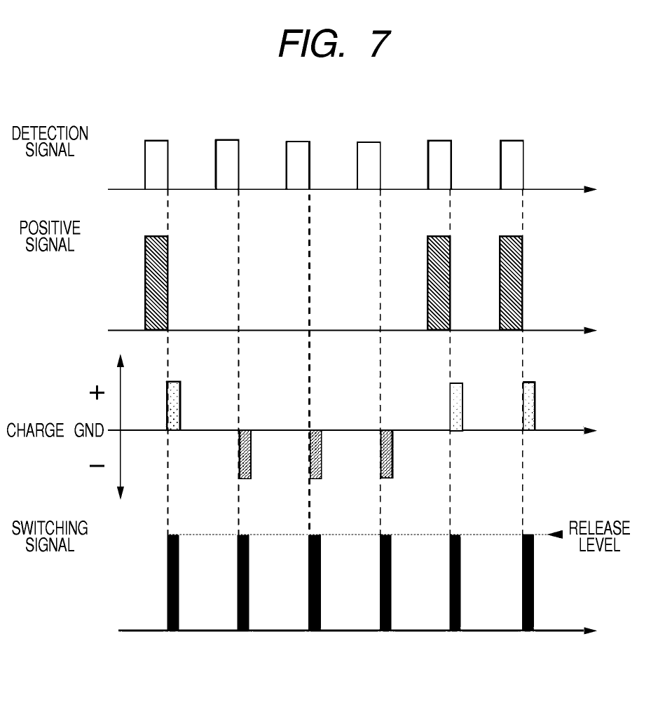

FIG. 7 shows one example of charge timing in the charge part 1111. In FIG. 7, a detection signal and a positive signal from the detection part 2, charge timing in the charge part 1111 and a switching signal to be inputted into the valve of the fluid introduction part 12 are chronologically shown from the upper row in that order.

FIG. 7 shows the case where the switching signal is outputted into the valve every detection signal of the fine particle P which is detected by the detection part 2 to introduce the fluid into connection part 13, thereby dividing the dispersion every one fine particle P, and the detection part 2 judges that the fine particle P has desired optical properties, and a positive signal is outputted, plus charge is imparted by the charge part 1111. At that time, when the detection part 2 judges that the fine particle P does not have desired optical properties, and a positive signal is not outputted, minus charge is imparted by the charge part 1111.

By controlling the charge by the charge part 1111 at this timing, as illustrated in FIG. 6, it is possible to send only the fine particle P having desired optical properties into the liquid sending route 112 so as to be contained in the dispersion having plus charge and to aliquot it into the branch channel 114.

Charge to the detection signal and positive signal, delay time and intensity of the switching signal, phase, pulse width and the like are properly set according to a sending rate of the fine particle P in the introduction route 111 and a distance between the detection part 2 and the connection part 3.

Also, in the case where aliquoting is carried out on the basis of the magnetization imparted to the dispersion, it is possible to achieve the aliquotion by generating a magnetic field (or switching a magnetic field) at appropriate timing according to a sending rate of the fine particle P in the introduction route 111 relative to the detection signal and positive signal and a distance between the detection part 2 and the branch part 14 and the like.

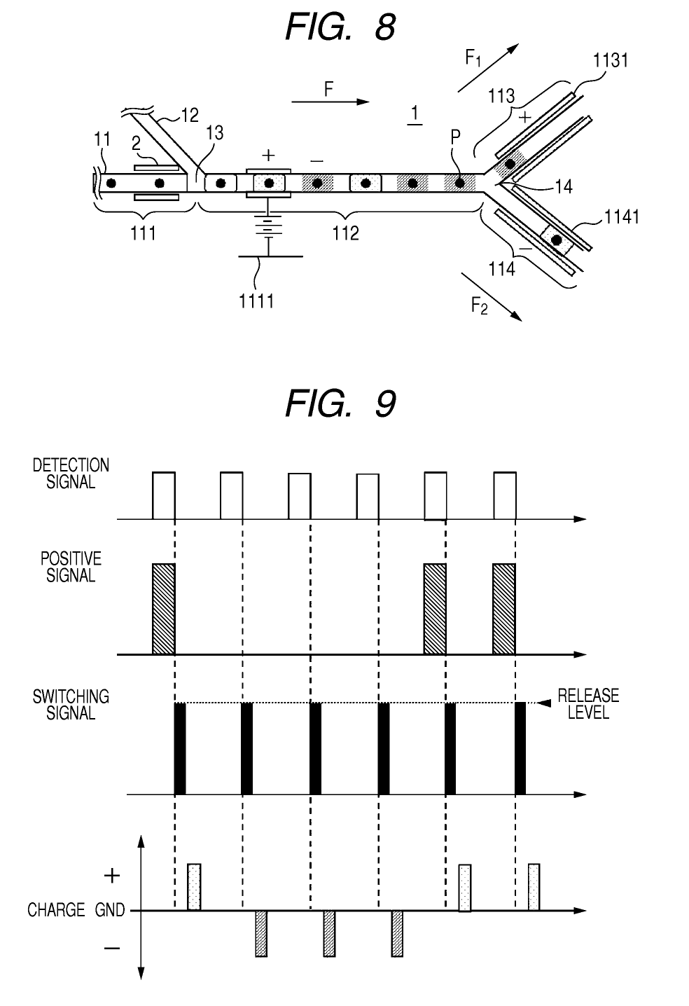

FIG. 8 is a schematic view (top view) showing a channel disposed on a substrate of a liquid sending apparatus according to Fourth Embodiment of the present invention.

In this embodiment, the charge part 1111 is configured as a microelectrode disposed on the surface of the liquid sending route 112, and a charge is imparted to the dispersion which has been divided by introducing the fluid from the fluid introduction part 12. Also, the detection part 2 is configured as a microelectrode to judge electric properties of the fine particle P, whereby aliquotion of the fine particle P may be achieved on the basis of a result thereof.

By detecting a change in impedance flowing between the electrodes, the detection part 2 detects the fine particle P and judges the electrical properties thereof, thereby outputting a signal regarding whether or not the fine particle P is to be aliquoted. In the case where a positive signal is outputted from the detection part 2, for example, the charge part 1111 applies a plus voltage to the dispersion containing the fine particle P out of the dispersions which are divided and sent in the liquid sending rout 112, thereby aliquoting the fine particle P in the branch channel 114.

FIG. 9 shows one example of charge timing in the charge part 1111 in this embodiment. In FIG. 9, a detection signal and a positive signal from the detection part 2, a switching signal to the valve of the fluid introduction part 12 and charge timing in the charge part 1111 are chronologically shown from the upper row in that order.

In the light of the above, in accordance with the liquid sending method and the liquid sending apparatus according to the embodiment of the present invention, by dividing the dispersion of fine particles flowing in the channel every prescribed number of fine particles and imparting a charge according to the properties of the fine particle to be contained in the dispersion to the divided dispersion, it is possible to aliquot the fine particle.

Accordingly, in comparison with the existing method and apparatus for imparting an acting force directly to the fine particle and moving it in the liquid, by aliquoting the fine particle in the channel on the basis of the charge of the dispersion, it is possible to control the sending direction of the fine particle rapidly and simply, and it is possible to aliquot the fine particle at a high speed and with high precision. Also, it is possible to suppress the amount of the liquid to be flown in the channel and to recover the fine particle after aliquoting in a high concentration.

### 4. Aliquotion of Fine Particle by Reaction Detection of Material

Next, a further embodiment of the liquid sending method and the liquid sending apparatus according to the embodiment of the present invention is described.

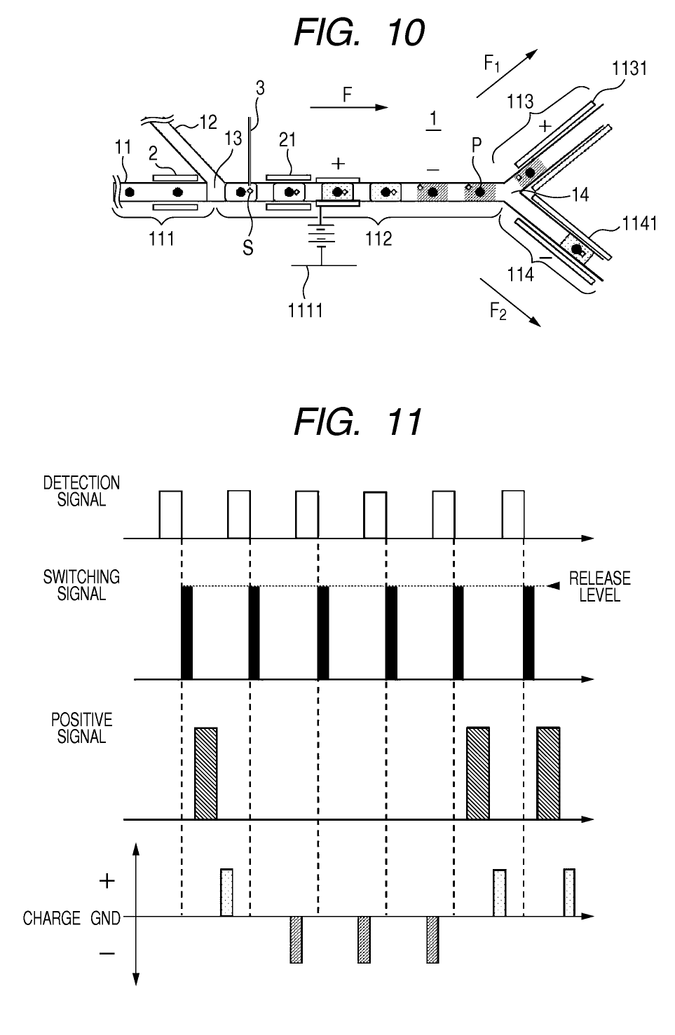

FIG. 10 is a schematic view (top view) showing a channel disposed on a substrate of a liquid sending apparatus according to Fifth Embodiment of the present invention.

In this embodiment, in addition to the configurations which have been described, there are provided an injection part 3 for injecting a prescribed material (see a symbol S in FIG. 10) into the fine particle-containing dispersion which has been divided in the liquid sending route 112 and a reaction detection part 21 for detecting a reaction between the injected material S and the fine particle P.

For example, in the case where the fine particle P is a cell, a microorganism or a biological polymer material, the injection part 3 is the part injecting a physiologically active material or an antibody capable of reacting with such a material or a reagent of every kind into the dispersion. Also, in the case where the fine particle P is an organic polymer material, an inorganic polymer material or a metal, for example, a compound capable of reacting with such a material is injected. Furthermore, it is also possible to inject an indicator capable of electrically or optically detecting the temperature or concentration, the pH or the like by the reaction detection part 21. As to these materials, a plural number of these materials may be simultaneously injected, or one or more materials among plural materials may be selectively injected. Furthermore, a plural number of the injection part 3 can be disposed in the liquid sending route 112, whereby the materials can be injected into the divided respective dispersions from all of the injection parts or selectively from any one of the injection parts.

Similar to the detection part 2, the reaction detection part 21 is disposed as a pair of microelectrodes on the both sides of the liquid sending route 111 and an alternating voltage is applied between the electrodes, thereby detecting a reaction between the material S injected from the injection part 3 and the fine particle P due to a change of impedance flowing between the electrodes. As described previously, the detection part 2 and the reaction detection part 21 may be configured as an optical detection system.

The reaction between the material S injected from the injection part 3 and the fine particle P is detected by a change of electrical properties and optical properties of the fine particle P to be caused by the reaction with the material S. First of all, the fine particle P to be sent in the introduction route 111 is judged with respect to electrical properties or optical properties by the detection part 2. Next, after injecting the material S from the injection part 3 into the dispersion divided in the liquid sending route 112, the electrical properties or optical properties are judged by the reaction detection part 21. Then, the reaction between the material S and the fine particle P is detected by a change of the judgment result of electrical properties or optical properties obtained from the detection part 2 and the reaction detection part 21.

In the case where the reaction between the material S and the fine particle P is detected, the reaction detection part 21 outputs a positive signal. The charge part 1111 imparts a plus or minus charge to the dispersion on the basis of this positive signal. According to this, it is possible to aliquot the fine particle P from which the reaction has been detected in either one of the branch channel 113 or the branch channel 114 on the basis of the charge of the dispersion.

FIG. 11 shows one example of charge timing of the charge part 1111 in this embodiment. In FIG. 9, a detection signal from the detection part 2, a switching signal to be inputted into the valve of the fluid introduction part 12, a positive signal from the reaction detection part 21 and charge timing in the charge part 1111 are chronologically shown from the upper row in that order.

In the light of the above, according to this embodiment, it is possible to aliquot only the group of the fine particles P which have reacted with a prescribed material S.

As a specific example, by using a micro bead in which a nucleic acid probe is solidified as the fine particle P and injecting a nucleic acid chain including a target nucleic acid chain and an intercalating fluorescent dye as the material S, it is possible to detect hybridization between the nucleic acid probe and the target nucleic acid chain by fluorescence and to aliquot only the hybridized micro beads.

Also, for example, by using a cell as the fine particle P and using a fluorescent labeled antibody against a cell surface antigen as the material S, it is possible to aliquot only a cell group capable of expressing a specified surface antigen by selectively detecting the fluorescence from the fluorescent labeled antibody bound with the cell surface antigen.

### 5. Reaction Analysis Method and Reaction Analysis Apparatus

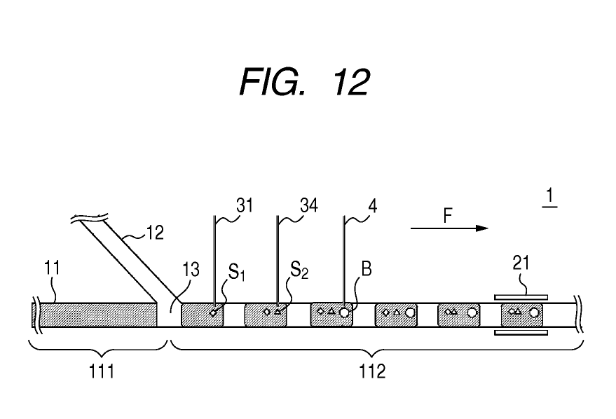

FIG. 12 is a schematic view (top view of channel) explaining a reaction analysis method utilizing the liquid sending method according to the present invention.

FIG. 12 illustrates a method in which a reaction buffer solution to be sent from the introduction route 111 is divided by properly introducing the fluid from the fluid introduction part 12 and sent to the liquid sending route 112, thereby detecting a prescribed reaction in the divided reaction buffer solution.

In FIG. 12, symbols 31 and 32 each stand for an injection part for injecting a prescribed material into the reaction buffer solution divided in the liquid sending route 112. In FIG. 12, the case where a material S₁ is injected from the injection part 31, a material S₂ is injected from the injection part 32, and a reaction between the material S₁ and the material S₂ is detected in the reaction detection part 21 is illustrated.

A plural number of each of the injection parts 31 and 32 can be disposed in the liquid sending route 112, whereby materials can be injected into the divided respective reaction buffer solutions from all of the injection parts or selectively from any one of the injection parts. Also, plural materials may be simultaneously injected, or at least one material among plural materials may be selectively injected from each of the injection parts.

As one example, for the purpose of screening a material capable of reacting with the single material S₁ to be injected from the injection part 31, every one of plural candidate materials is successively injected as the material S₂ into each of the divided reaction buffer solutions from the injection part 32, thereby detecting the presence or absence of a reaction in each of the reaction buffer solutions in the reaction detection part 21. Besides, by introducing a reaction buffer solution in which a prescribed material has been contained into the channel 11, it is also possible to achieve two-stage screening by injecting a candidate material capable of undergoing a primary reaction with the foregoing material from the injection part 31 and injecting a secondary reaction candidate material capable of reacting with a primary reaction product from the injection part 32.

Also, it is possible to apply it to PCR. For example, when a reaction solution in which template DNA for amplification and a salt, nucleotide (dTNPs), etc. have been contained is introduced into the channel 11, plural combinations of forward and reverse primers are injected from the injection part 31 and the injection part 32, respectively, and the presence or absence of a reaction in each of the reaction solutions is detected in the reaction detection part 21, a primer set capable of efficiently amplifying the template DNA can be found out.

As described previously with reference to FIG. 11, the reaction detection part 21 is disposed as a pair of microelectrodes on the both sides of the liquid sending route 111 and an alternating voltage is applied between the electrodes, thereby detecting a reaction between the material S₁ and the material S₂ on the basis of a change of impedance flowing between the electrodes. As described previously, the reaction detection part 21 may be configured as an optical detection system.

In FIG. 12, a symbol 4 stands for a bead introduction part for injecting a microbead for identification (see a symbol B in FIG. 12) for identification the divided individual reaction buffer solutions.

As the micro bead B for identification, used is a magnetic bead or a fluorescent bead which is individually different in electrical properties or optical properties, and can be specified by obtaining its characteristic value of electrical properties or optical properties as an identification signal. The identification signal of the micro bead B for identification can be detected by measuring the electrical properties or optical properties by the reaction detection part 21. Also, by using a fluorescent bead in which the quantity of fluorescence reversibly changes depending upon the temperature, it is possible to measure the temperature in the reaction detection part 21 regarding the divided individual reaction buffer solutions. Besides, various beads made of glass or polystyrene which have been subjected to surface modification (processing) or internal modification (processing) so that temperature, fluorescence, scattered light, magnetization, charge, shape concentration or the like can be measured and detected as an identification signal by the reaction detection part 21, can be adopted as the micro bead B for identification.

In the bead introduction part 4, such a bead is introduced into the divided reaction buffer solutions before or after the injection of the materials S₁ and S₂ in the injection parts 31 and 32.

For example, for the purpose of screening a material capable of reacting with the single material S₁ to be injected from the injection part 31, in the case where plural candidate materials as the material S₂ are successively injected into each of the divided reaction buffer solutions from the injection part 32, one after another different micro beads B for identification, depending upon the material S₂ to be injected from the injection part 32, are introduced into the reaction buffer solution from the bead introduction part 4. Then, by detecting the reaction between the material S₁ and the material S₂ and detecting the identification signal from the micro bead B for identification in the reaction detection part 21, it is possible to know which candidate material is material injected into the reaction buffer solution from which the reaction has been detected on the basis of the correlation between the material S₂ and the micro bead B for identification.

In the light of the above, on the basis of the liquid sending method according to the present invention, by dividing the reaction buffer solution flowing in the channel and injecting various materials into the divided reaction buffer solutions, it is possible to simultaneously analyze plural chemical reactions in a single channel. Accordingly, in comparison with the existing method for achieving a reaction in a liquid to be continuously sent in a microchip channel, it is possible to give the reaction analysis high through put.

In the reaction analysis method on the basis of the liquid sending method according to the present invention, different from the foregoing case of achieving aliquoting a fine particle, the fluid for dividing the reaction buffer solution may be a gas or a liquid, and there is the case where this liquid does not always need to have electrically or magnetically insulating property. However, in case of detecting the chemical or magnetic properties of the micro bead B for identification, it is preferable to use a liquid with insulating property.

It should be understood by those skilled in the art that various modifications, combinations, sub-combinations and alternations may occur depending on design requirements and other factors insofar as they are within the scope of the appended claims or the equivalents thereof.

What is claimed is:

1. A liquid sending method comprising the step of:
introducing either one fluid of a gas or an insulating liquid into a channel disposed on a substrate, thereby dividing a liquid flowing in the channel and sending the liquid.

2. The liquid sending method according to claim 1, wherein in the channel through which a dispersion of fine particles flows, the fluid is introduced between the fine particles, thereby dividing the dispersion flowing in the channel every prescribed number of fine particles and sending the liquid.

3. The liquid sending method according to claim 2, wherein the sending direction is controlled on the basis of charge or magnetization imparted to the divided dispersion, thereby sorting the fine particles.

4. The liquid sending method according to claim 3, wherein a material is injected into the divided dispersion, and a reaction between the material and the fine particle is detected, thereby imparting the charge on the basis of the detection result.

5. A reaction analysis method comprising the steps of:
injecting plural materials into the divided liquid by the method according to claim 1; and
detecting a reaction between the materials.

6. The reaction analysis method according to claim 5, further comprising the steps of:
injecting a micro bead for identification into the divided liquid; and
detecting a identification signal from the micro bead for identification.

7. The reaction analysis method according to claim 6, wherein the identification signal is detected by measuring at least one of the following: temperature, fluorescence, scattered light, magnetization, charge, shape and concentration, of the micro bead for identification.

8. A liquid sending apparatus comprising:
a fluid introduction part for introducing either one fluid of a gas or an insulating liquid into a channel disposed on a substrate, thereby dividing a liquid flowing in the channel and sending the liquid.

9. The liquid sending apparatus according to claim 8, wherein hydrophobic property or electrical insulating property is imparted to the surface of the channel facing the liquid.
